(19) United States
(12) Patent Application Publication
(10) Pub. No.: US 2026/0255475 A1
(43) Pub. Date: Aug. 27, 2026

(54) CIRCUIT BOARD AND MANUFACTURING METHOD THEREOF

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventors: Yang LI, Hebei Province (CN); Chao WANG, Hebei Province (CN)

(21) Appl. No.: 19/063,214

(22) Filed: Feb. 25, 2025

(51) Int. Cl. H05K 1/02; H05K 3/46

(52) U.S. Cl. CPC H05K 1/0281; H05K 3/4635; H05K 3/4697; H05K 2201/0195; H05K 2201/05; H05K 2201/0753; H05K 2201/2009; H05K 2203/0228

(57) ABSTRACT

A circuit board includes a first exterior structure, a second exterior structure, an interior structure, and a composite material layer. The first exterior structure includes a first exterior reinforcement layer disposed in the first exterior structure. The second exterior structure includes a second exterior reinforcement layer disposed in the second exterior structure. The interior structure is disposed between the first exterior structure and the second exterior structure, wherein the interior structure has a cavity extending along a first direction, the cavity is formed through the interior structure, the first exterior reinforcement layer is located on a top of the cavity, the cavity exposes a portion of the first exterior reinforcement layer, the second exterior reinforcement layer is located on at a bottom of the cavity, and the cavity exposes a portion of the second exterior reinforcement layer.

### BACKGROUND

### Field of Invention

The present disclosure relates to a circuit board and a manufacturing method of the circuit board. More particularly, the present disclosure relates to the circuit board having exterior reinforcement layers and the manufacturing method thereof.

### Description of Related Art

With the development of technologies such as 5G (5th Generation Wireless Systems) and artificial intelligence, the increasing demand for higher density, faster transmission rate, and stronger environmental adaptability has driven flexible circuit boards to the development of smaller line widths (or spacing) and higher layer counts.

Flexible printed circuits (FPCs) are flexible and suitable for applications that require the installation of electronic components in small or non-planar areas, allowing FPCs to achieve complex electrical connections in a smaller space. Compared with conventional rigid circuit boards (Printed circuit boards; PCBs), FPCs are lighter and thinner, which helps reduce the weight of the final product.

Typically, steel sheets are disposed on one side of the conventional flexible circuit board, and electronic components are disposed on the other side of the flexible circuit board, in which steel sheets are configured to provide support for the electronic components. However, the steel sheets have disadvantages such as being heavy and occupying a large area. Furthermore, since the steel sheets disposed on one side of the flexible circuit board, the electronic components can only are disposed the other side of the flexible circuit board, resulting in a limited number of electronic components connected to the flexible circuit board, thereby reducing the functional integration capability.

### SUMMARY

The circuit board provided by the present disclosure has a first exterior reinforcement layer, a second exterior reinforcement layer, and a composite material layer, which are embedded in the circuit board, so that electronic components can be additionally disposed at relative positions on both sides of the outside of the circuit board, thereby increasing the degree of freedom of the circuit design, the space utilization rate, and the functional integration capability.

One example of the present disclosure is to provide a circuit board including a first exterior structure, a second exterior structure, an interior structure, and a composite material layer. The first exterior structure includes a first exterior reinforcement layer disposed in the first exterior structure. The second exterior structure includes a second exterior reinforcement layer disposed in the second exterior structure. The interior structure is disposed between the first exterior structure and the second exterior structure, with the first exterior structure, the interior structure, and the second exterior structure stacked in sequence along a first direction. The interior structure has a cavity extending along the first direction, which is formed through the interior structure. The first exterior reinforcement layer is located on a top of the cavity, and the cavity exposes a portion of the first exterior reinforcement layer. The second exterior reinforcement layer is located on a bottom of the cavity, and the cavity exposes a portion of the second exterior reinforcement layer. The composite material layer surrounds the cavity, the first exterior structure, and the second exterior structure.

One example of the present disclosure is to provide manufacturing method of a circuit board. The method includes the following steps: providing a first original exterior structure, an interior base board, and a second original exterior structure stacked in sequence along a first direction, in which the first original exterior structure includes a first original insulating layer and a first exterior wiring layer facing the interior base board, in which the first original insulating layer includes a first main portion and a first extended portion connecting to the first main portion, the first exterior wiring layer is disposed on the first extended portion, in which the second original exterior structure includes a second original insulating layer and a second exterior wiring layer facing the interior base board, in which second original insulating layer includes a second main portion and a second extended portion connecting to the second main portion, and the second exterior wiring layer is disposed on the second extended portion; removing a portion of the interior base board, a portion of the first main portion, and a portion of the second main portion to form a through hole penetrating along the first direction in the interior base board and expose a portion of a sidewall of the interior base board; forming a first composite material on the portion of a sidewall of the interior base board, the portion of the first main portion, and the portion of the second main portion; forming a first exterior reinforcement layer on the first composite material and in the first original insulating layer, and forming a second exterior reinforcement layer on the first composite material an in the second original insulating layer to close the through hole and form a cavity in the interior base board, in which the cavity exposes a portion of the first exterior reinforcement layer and a portion of the second exterior reinforcement layer; forming a second composite material covering the first exterior reinforcement layer and the second exterior reinforcement layer; bending the first extended portion and the first exterior wiring layer to cover the first main portion; bending the second extended portion and the second exterior wiring layer to cover the second main portion; and performing a cutting step to separate the first extended portion and the first main portion and separate the second extended portion and the second main portion.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a circuit board in accordance with a first embodiment of the present disclosure.

FIG. 2 is a cross-sectional view of a circuit board in accordance with a second embodiment of the present disclosure.

FIG. 3 is a cross-sectional view of a circuit board in accordance with a third embodiment of the present disclosure.

FIG. 4A to FIG. 4C are cross-sectional views of various stages of an interior base board in accordance with some embodiments of the present disclosure.

FIG. 5A and FIG. 5B are cross-sectional views of various stages of a first original exterior structure (or a second original exterior structure) in accordance with some embodiments of the present disclosure.

FIG. 6A to FIG. 6F are cross-sectional views of various stages of the circuit board in accordance with the first embodiment of the present disclosure.

### DETAILED DESCRIPTION

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

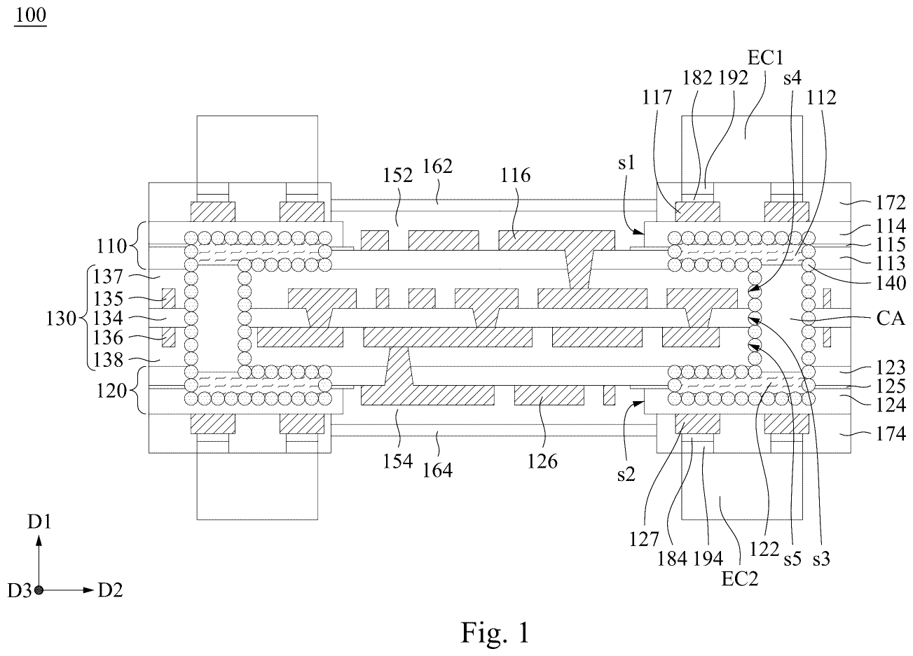

FIG. 1 is a cross-sectional view of a circuit board 100 in accordance with a first embodiment of the present disclosure. The circuit board 100 includes a first exterior structure 110, a second exterior structure 120, an interior structure 130, and a composite material layer 140. The first exterior structure 110 includes a first exterior reinforcement layer 112 disposed in the first exterior structure 110. The second exterior structure 120 includes a second exterior reinforcement layer 122 disposed in the second exterior structure 120. The interior structure 130 is disposed between the first exterior structure 110 and the second exterior structure 120, in which the first exterior structure 110, the interior structure 130, and the second exterior structure 120 are stacked in sequence along a first direction D1, in which the interior structure 130 has a cavity CA extending along the first direction D1, the cavity CA is formed through the interior structure 130, the first exterior reinforcement layer 112 is located on a top of the cavity CA, the cavity CA exposes a portion of the first exterior reinforcement layer 112, the second exterior reinforcement layer 122 is located on a bottom of the cavity CA, and the cavity CA exposes a portion of the second exterior reinforcement layer 122. The composite material layer 140 surrounds the cavity CA, the first exterior structure 110, and the second exterior structure 120. Specifically, the composite material layer 140 surrounds the cavity CA, the first exterior reinforcement layer 112, and the second exterior reinforcement layer 122. In other words, the cavity CA is located between the first exterior reinforcement layer 112 and the second exterior reinforcement layer 122.

As shown in FIG. 1, the interior structure 130 further includes an interior insulating layer 134, a wiring layer 135, a wiring layer 136, a first interior adhesion layer 137, and a second interior adhesion layer 138. The wiring layer 135 and the wiring layer 136 are respectively disposed on both sides of the interior insulating layer 134. The first interior adhesion layer 137 is disposed between the interior insulating layer 134 and the first exterior structure 110. The second interior adhesion layer 138 is disposed between the interior insulating layer 134 and the second exterior structure 120. Specifically, the first interior adhesion layer 137 covers the wiring layer 135 and contacts the one surface of the interior insulating layer 134, and the second interior adhesion layer 138 covers the wiring layer 136 and contacts the other surface of the interior insulating layer 134.

As shown in FIG. 1, the first exterior structure 110 further includes a first exterior insulating layer 113, a second exterior insulating layer 114, a first exterior adhesion layer 115, a wiring layer 116, and a first exterior wiring layer 117. The first exterior insulating layer 113 is disposed on the first interior adhesion layer 137. The second exterior insulating layer 114 is disposed above the first exterior insulating layer 113 and the cavity CA, in which a portion of the first exterior insulating layer 113 protrudes from a sidewall s1 of second exterior insulating layer 114 in a second direction D2, and the second direction D2 is substantially perpendicular to the first direction D1. The wiring layer 116 is disposed on the first exterior insulating layer 113, and the first exterior wiring layer 117 is disposed on the second exterior insulating layer 114.

Specifically, as shown in FIG. 1, the first exterior adhesion layer 115 is disposed between the first exterior insulating layer 113 and the second exterior insulating layer 114, in which the first exterior reinforcement layer 112 is disposed between the second exterior insulating layer 114 and the cavity CA, and the composite material layer 140 surrounds the first exterior reinforcement layer 112 and contacts the first exterior insulating layer 113, the first exterior adhesion layer 115, and the second exterior insulating layer 114. More specifically, the composite material layer 140 surrounds most of the surfaces of the first exterior reinforcement layer 112 and exposes a portion of the surface of the first exterior reinforcement layer 112 facing the cavity CA. A width of the first exterior reinforcement layer 112 is greater than a width of the cavity CA. A width of the second exterior insulating layer 114 is greater than a width of the first exterior reinforcement layer 112.

As shown in FIG. 1, the second exterior structure 120 further includes a third exterior insulating layer 123, a fourth exterior insulating layer 124, a second exterior adhesion layer 125, a wiring layer 126, and a second exterior wiring layer 127. The third exterior insulating layer 123 is disposed on the second interior adhesion layer 138. The fourth exterior insulating layer 124 is disposed above the third exterior insulating layer 123 and the cavity CA, in which a portion of the third exterior insulating layer 123 protrudes from a sidewall s2 of the fourth exterior insulating layer 124 in the second direction D2. The wiring layer 126 is disposed on the third exterior insulating layer 123, and the second exterior wiring layer 127 is disposed on the fourth exterior insulating layer 124.

Specifically, as shown in FIG. 1, the second exterior adhesion layer 125 is disposed between the third exterior insulating layer 123 and the fourth exterior insulating layer 124, in which second exterior reinforcement layer 122 is disposed between the fourth exterior insulating layer 124 and the cavity CA, and the composite material layer 140 surrounds the second exterior reinforcement layer 122 and contacts the third exterior insulating layer 123, the second exterior adhesion layer 125, and the fourth exterior insulating layer 124. More specifically, the composite material layer 140 surrounds most of the surfaces of the second exterior reinforcement layer 122 and exposes a portion of the surface of the second exterior reinforcement layer 122 facing the cavity CA. A width of the second exterior reinforcement layer 122 is greater than a width of the cavity CA. A width of the fourth exterior insulating layer 124 is greater than a width of the second exterior reinforcement layer 122.

In some examples, the materials of the interior insulating layer 134, the first exterior insulating layer 113, the second exterior insulating layer 114, the third exterior insulating layer 123, and the fourth exterior insulating layer 124 may be insulating materials such as polyimide (PI), glass fiber epoxy resin (FR4), polyethylene terephthalate (PET), polyethylene naphthalate (PEN), or polyethylene (PE), but is not limited thereto.

In some examples, the wiring layer 116, the first exterior wiring layer 117 the wiring layer 126, the second exterior wiring layer 127, the wiring layer 135, and the wiring layer 136 may be formed by an additive method, a semi-additive method, or a subtractive method. In some examples, the materials of the wiring layer 116, the first exterior wiring layer 117, the wiring layer 126, the second exterior wiring layer 127, the wiring layer 135, and the wiring layer 136 may be conductive materials such as copper, gold, or silver, but is not limited thereto.

In some examples, the materials of the first exterior adhesion layer 115, the second exterior adhesion layer 125, the first interior adhesion layer 137, and the second interior adhesion layer 138 may be low flow prepreg or non-flow prepreg.

It could be understood that the number of the insulating layers (for examples, the interior insulating layer 134, the first exterior insulating layer 113, the second exterior insulating layer 114, the third exterior insulating layer 123, and the fourth exterior insulating layer 124) in the circuit board 100 and the number of the wiring layers (for examples, the wiring layer 116, the wiring layer 126, the wiring layer 135, and the wiring layer 136) are not limited to that shown in FIG. 1. In other words, in other embodiments, the circuit board 100 may include more insulating layers and wiring layers.

In the first embodiment of FIG. 1, the first exterior reinforcement layer 112 the second exterior reinforcement layer 122, and the cavity CA are aligned with each other in the first direction D1. In some examples, a projection of the first exterior wiring layer 117 on the interior insulating layer 134 overlaps a projection of the second exterior wiring layer 127 on the interior insulating layer 134.

The first exterior reinforcement layer 112 and the second exterior reinforcement layer 122 in FIG. 1 may also be referred to as glass fiber reinforced plastic (GFRP). In some examples, the materials of the first exterior reinforcement layer 112 and the second exterior reinforcement layer 122 include fiber glass and thermoset resin. Thermoset resin may be such as epoxy resin or polyester resin, but is not limited thereto. In a specific example, the materials of the first exterior reinforcement layer 112 and the second exterior reinforcement layer 122 each include 62% of fiber glass and 38% of thermoset resin. Compared with conventional metal materials such as steel sheets, the first exterior reinforcement layer 112 and the second exterior reinforcement layer 122 have the characteristics of high strength and light weight. Therefore, the first exterior reinforcement layer 112 and the second exterior reinforcement layer 122 can provide good mechanical properties for the circuit board 100 and help reduce the weight of the circuit board 100.

As shown in FIG. 1, the composite material layer 140 is further disposed on a sidewall s3 of the interior insulating layer 134, a sidewall s4 of the first interior adhesion layer 137, and a sidewall s5 of the second interior adhesion layer 138. In other words, the composite material layer 140 is disposed between the sidewall s3 and the cavity CA, between the sidewall s4 and the cavity CA, and between the sidewall s5 and the cavity CA. The composite material layer 140 in the interior structure 130, the first exterior reinforcement layer 112 in the first exterior structure 110, and the second exterior reinforcement layer 122 in the second exterior structure 120 form the cavity CA.

The composite material layer 140 is composed of a plurality of columnar materials, and each columnar material extends along a third direction D3 substantially perpendicular to the first direction D1. It could be understood that the first direction D1, the second direction D2, and the third direction D3 are substantially perpendicular to each other. The plurality of columnar materials is arranged as a single-layer closed structure. Specifically, a cross-sectional view of each columnar material is circular, as shown in FIG. 1. The composite material layer 140 could also be understood to be composed of a plurality of cylindrical materials.

The composite material layer 140 in FIG. 1 is configured to provide local support for the circuit board 100. Specifically, when the circuit board 100 is subjected to external forces, the columnar materials in the composite material layer 140 can provide good mechanical properties. More specifically, the composite material layer 140 has a small surface area and volume ratio. Specifically, compared to other shapes (e.g., a cuboid), a cylinder has a smaller surface area for the same volume. This means that under a given external force, the pressure per unit area is relatively low, which helps to improve the material's compressive resistance.

In some examples, each columnar material in the composite material layer 140 includes a plurality of ceramic particles, fiber reinforcement material, and graphene material. The ceramic particles may be, for example, aluminum oxide or silicon carbide. The fiber reinforcement material may be, for example, fiber glass or carbon fiber. The contents of ceramic particles, fiber reinforcement material, and graphene material may be adjusted according to specific performance requirements.

Referring to FIG. 1, the circuit board 100 further includes a dielectric layer 152, a covering layer 162, a solder mask layer 172, a gold plating layer 182, a tin paste 192, and an electronic component EC1. The dielectric layer 152 is disposed on the first exterior insulating layer 113, the covering layer 162 is disposed on the dielectric layer 152, the solder mask layer 172 is disposed on the second exterior insulating layer 114, the gold plating layer 182 and the tin paste 192 are disposed in the solder mask layer 172, and the electronic component EC1 is disposed on the tin paste 192.

Referring to FIG. 1, the circuit board 100 further includes a dielectric layer 154, a covering layer 164, a solder mask layer 174, a gold plating layer 184, a tin paste 194, and an electronic component EC2. The dielectric layer 154 is disposed on the third exterior insulating layer 123, the covering layer 164 is disposed on the dielectric layer 154, the solder mask layer 174 is disposed on the fourth exterior insulating layer 124, the gold plating layer 184 and the tin paste 194 are disposed in the solder mask layer 174, and the electronic component EC2 is disposed on the tin paste 194. The electronic component EC1 and the electronic component EC2 may be, for example, active components and passive components.

In FIG. 1, the first exterior wiring layer 117 and the second exterior wiring layer 127 are respectively located on opposite sides of the circuit board 100, so that electronic components (i.e., the electronic component EC1 and the electronic component EC2) can be located on both sides of the circuit board 100, thereby increasing of the functional integration capability of the circuit board 100. The circuit board 100 may be, for example, a flexible circuit board.

Compared to a circuit board with a solid structure, the cavity CA inside the circuit board 100 of the present disclosure is more resistant to bending stress. In other words, the circuit board 100 can improve the moment of inertia (also referred to as the second moment of area). Specifically, for a given mass or material amount, the moment of inertia of a cross-section about a given axis can be significantly increased by distributing the material farther from the central axis. This means that a member with a larger moment of inertia can better resist deformation when subjected to the same bending force. The cavity CA structure effectively increases its moment of inertia by using material at the edges of the cavity CA while leaving the interior space.

The circuit board 100 of the present disclosure has a support body formed by the embedded external reinforcement layer(s) (i.e., the first exterior reinforcement layer 112 and the second exterior reinforcement layer 122) and the composite material layer 140 to provide support for the electronic component(s) (i.e., the electronic component EC1 and the electronic component EC2). This design can provide support for the electronic components on both sides without damaging the structure of the circuit board 100, thereby improving the structural stability of the circuit board 100. Furthermore, the cavity CA provided in the support body can also reduce the stress generated during bending and improve the flexibility of the flexible circuit board. For example, better isolation can be achieved by placing certain sensitive circuits on one side and the power supply section on the other side. By placing components on both sides of the circuit board, the space utilization of the circuit board can be improved. Proper use of double-sided layout can make signal paths shorter and reduce interference, thereby increasing the electrical performance of the entire system. For example, in high-frequency applications, shorter traces can help reduce electromagnetic interference (EMI).

In the first embodiment of FIG. 1, two support bodies (i.e., the first exterior reinforcement layer 112, the second exterior reinforcement layer 122, and the composite material layer 140) are illustrated, in which the composite material layer 140 on one side of each support body substantially extends from the second exterior insulating layer 114, the first exterior adhesion layer 115, the first exterior insulating layer 113, the first interior adhesion layer 137, the interior insulating layer 134, the second interior adhesion layer 138, the third exterior insulating layer 123, the second exterior adhesion layer 125, and the fourth exterior insulating layer 124 along the first direction D1. The cross-sectional views of the two support bodies in FIG. 1 both have a similar C-shaped form.

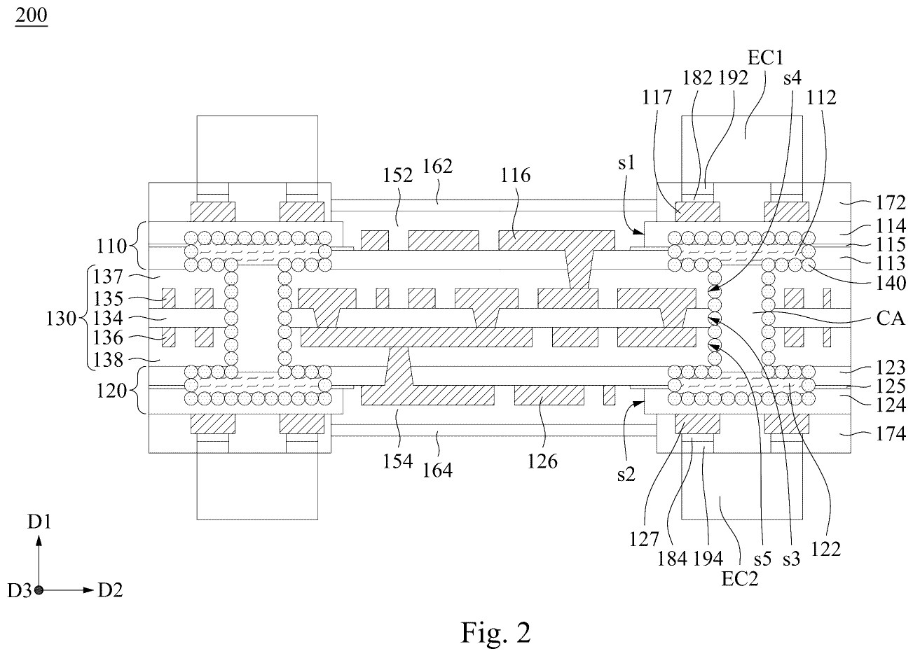

FIG. 2 is a cross-sectional view of a circuit board 200 in accordance with a second embodiment of the present disclosure. The circuit board 200 of FIG. 2 is similar to the circuit board 100 of FIG. 1, except that the cross-sectional views of the two support bodies (i.e., the first exterior reinforcement layer 112, the second exterior reinforcement layer 122, and the composite material layer 140) in FIG. 2 of the second embodiment both have a similar I-shaped form. In other words, the middle portion of the first exterior reinforcement layer 112 and the middle portion of the second exterior reinforcement layer 122 are exposed in the two support bodies.

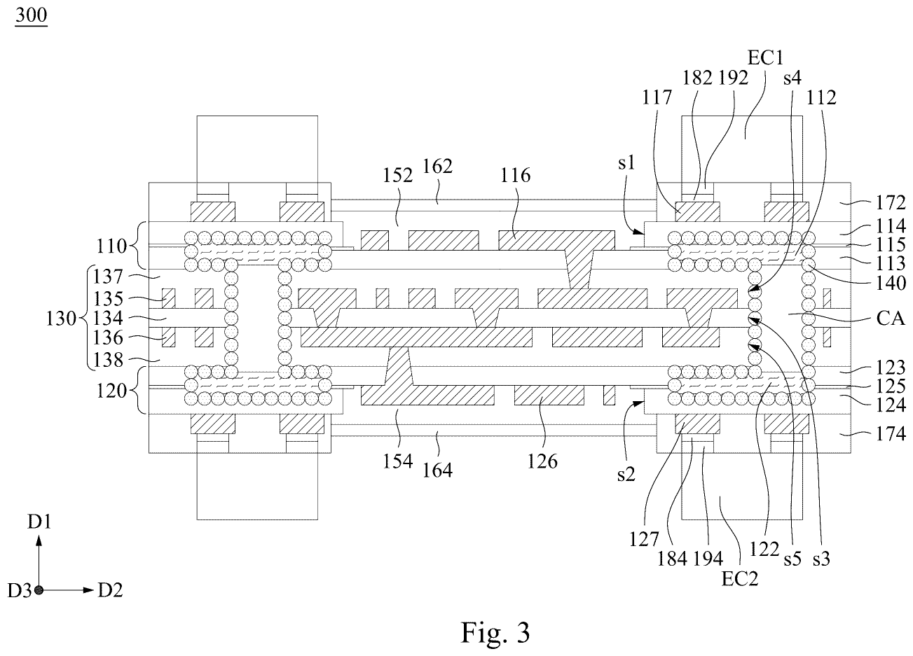

FIG. 3 is a cross-sectional view of a circuit board 300 in accordance with a third embodiment of the present disclosure. The circuit board 300 of FIG. 3 is similar to the circuit board 100 of FIG. 1, except that the cross-sectional view of one of the support bodies (i.e., the first exterior reinforcement layer 112, the second exterior reinforcement layer 122, and the composite material layer 140) in FIG. 3 of the third embodiment has a similar I-shaped form, and the cross-sectional view the other one of the support bodies has a similar C-shaped form.

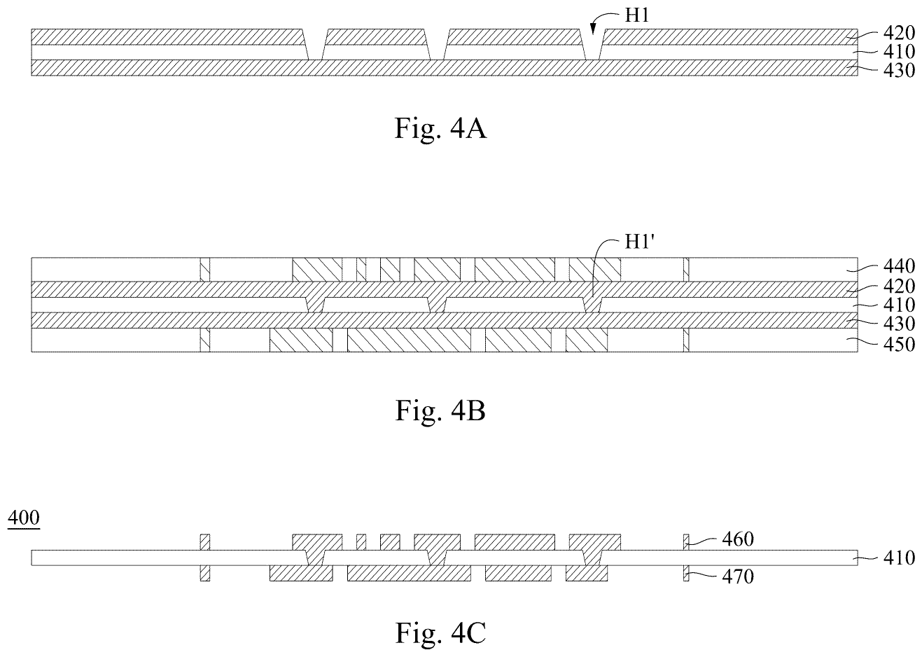

FIG. 4A to FIG. 4C are cross-sectional views of various stages of an interior base board 400 (referring to FIG. 4C) in accordance with some embodiments of the present disclosure. Referring to FIG. 4A, an initial wiring layer 420 and a metal layer 430 are respectively disposed on both sides of the initial insulating layer 410. A plurality of holes H1 may be formed in the initial wiring layer 420 and the initial insulating layer 410 by laser drilling.

Referring to FIG. 4A and FIG. 4B, electroplating and/or electroless plating is performed to form a plurality of vias H1′ in the initial wiring layer 420 and the initial insulating layer 410. Next, a photoresist layer 440 is formed on the initial wiring layer 420 and a photoresist layer 450 is formed on the metal layer 430. A photolithography process is performed using a mask (not shown) to form the interior base board 400 including a wiring layer 460 and a wiring layer 470, as shown in FIG. 4C.

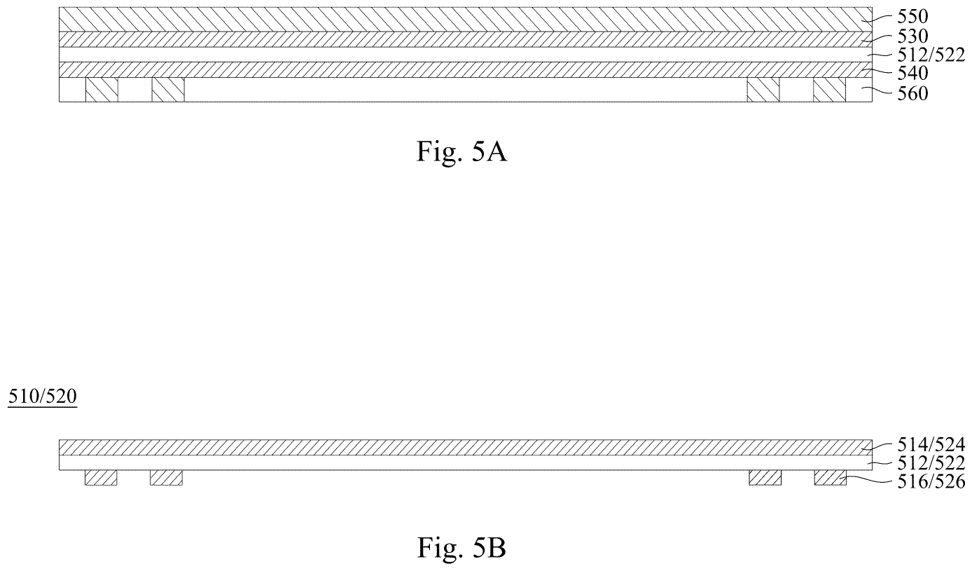

FIG. 5A and FIG. 5B are cross-sectional views of various stages of a first original exterior structure 510 (or a second original exterior structure 520) (referring to FIG. 5B) in accordance with some embodiments of the present disclosure. Referring to FIG. 5A, a metal layer 530 and a metal layer 540 are respectively disposed on both sides of a first original insulating layer 512 (or a second original insulating layer 522). Next, a photoresist layer 550 is formed on the metal layer 530, and a photoresist layer 560 is formed on the metal layer 540. After exposure and development processes are performed using a mask (not shown), etching and removal processes are performed to form the first original exterior structure 510 (or the second original exterior structure 520) having a wiring layer 514 (or a wiring layer 524) and a first exterior wiring layer 516 (or a second exterior wiring layer 526), as shown in FIG. 5B.

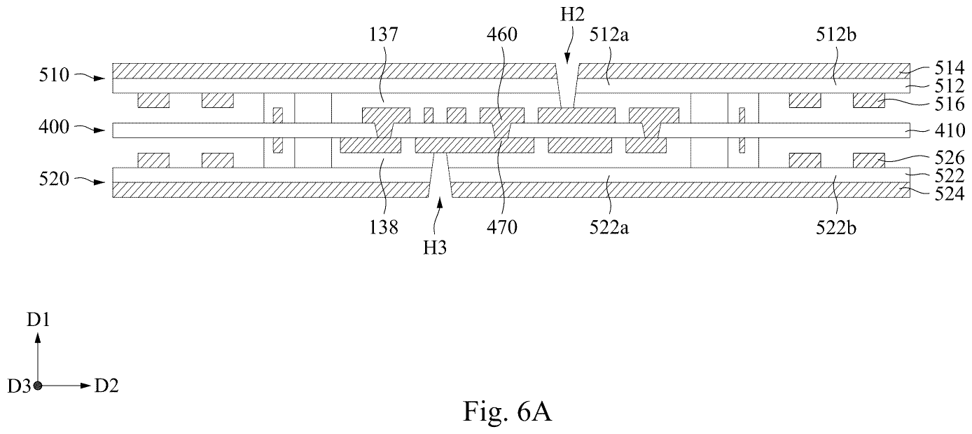

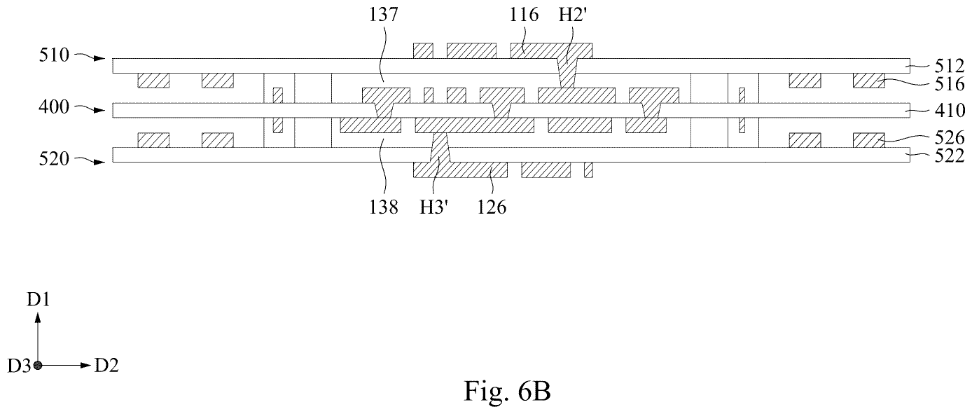

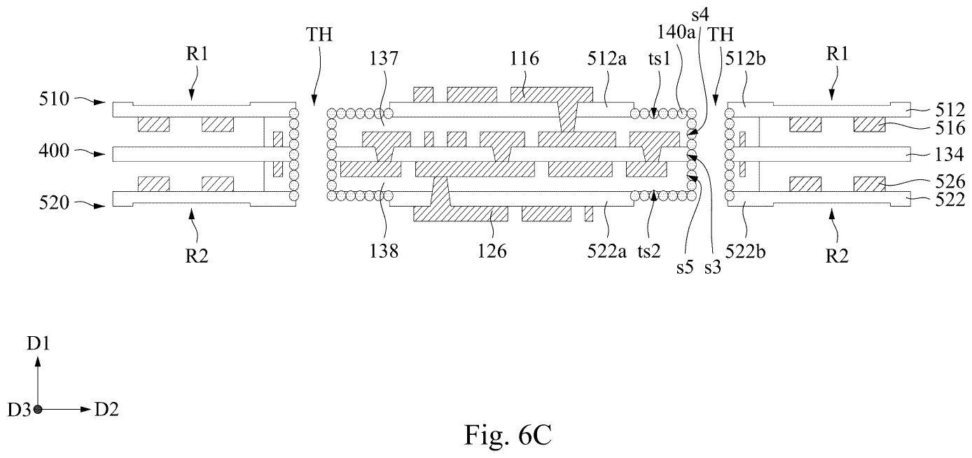

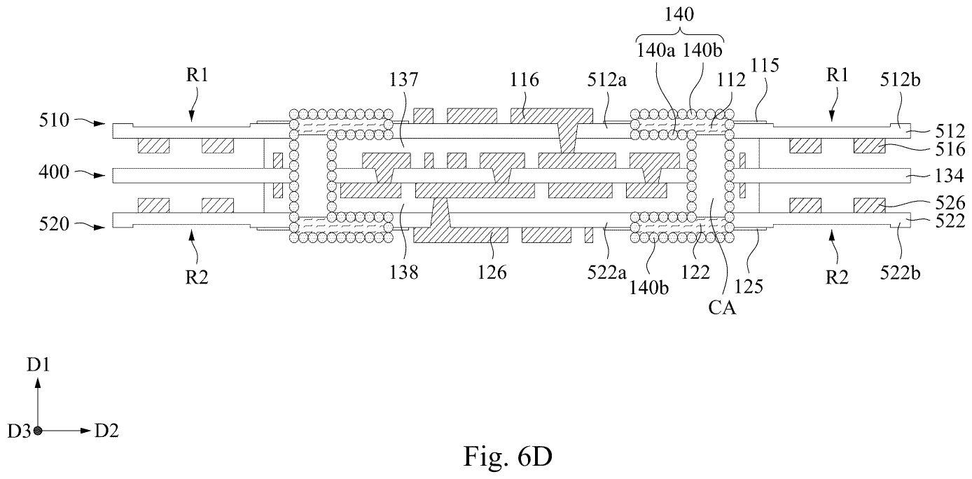

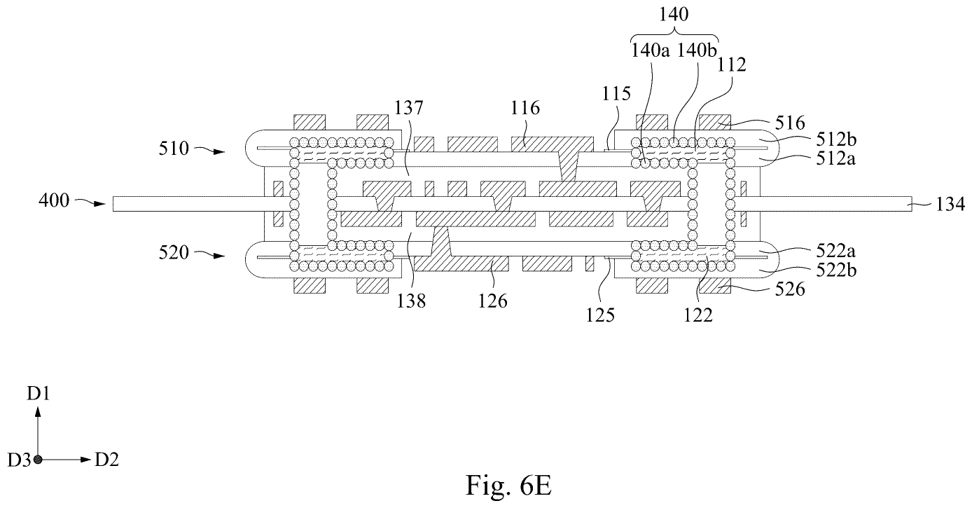

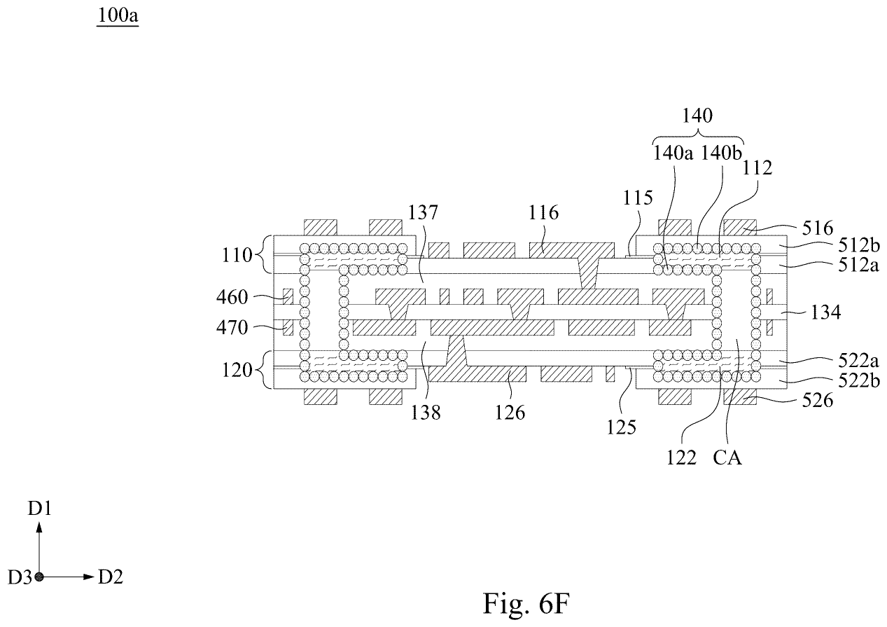

FIG. 6A to FIG. 6F are cross-sectional views of various stages of the circuit board 100a (referring to FIG. 6F) in accordance with the first embodiment of the present disclosure. As shown in FIG. 6A, the first original exterior structure 510, the interior base board 400, and the second original exterior structure 520 stacked in sequence along a first direction D1.

As shown in FIG. 6A, the first interior adhesion layer 137 is formed between the first original exterior structure 510 and the interior base board 400, and the second interior adhesion layer 138 is formed between the second original exterior structure 520 and the interior base board 400. The first original exterior structure 510, the first interior adhesion layer 137, the interior base board 400, the second interior adhesion layer 138, and the second original exterior structure 520 may be formed into an integrated structure by pressing.

As shown in FIG. 6A, the first original exterior structure 510 includes the first original insulating layer 512 and the first exterior wiring layer 516 facing the interior base board 400. The first original insulating layer 512 includes a first main portion 512a and a first extended portion 512b connecting to the first main portion 512a. The wiring layer 514 and the first exterior wiring layer 516 are respectively disposed on both sides of the first original insulating layer 512. Specifically, the wiring layer 514 is disposed on the first main portion 512a and the first extended portion 512b, and the first exterior wiring layer 516 is disposed on the first extended portion 512b. In other words, the first exterior wiring layer 516 is not disposed on the first main portion 512a.

As shown in FIG. 6A, the second original exterior structure 520 includes the second original insulating layer 522 and the second exterior wiring layer 526 facing the interior base board 400. The second original insulating layer 522 includes a second main portion 522a and a second extended portion 522b connecting to the second main portion 522a. The wiring layer 524 and the second exterior wiring layer 526 are respectively disposed on both sides of the second original insulating layer 522. Specifically, the wiring layer 524 is disposed on the second main portion 522a and the second extended portion 522b, and the second exterior wiring layer 526 is disposed on the second extended portion 522b. In other words, the second exterior wiring layer 526 is not disposed on the second main portion 522a.

Still referring to FIG. 6A, specifically, the first interior adhesion layer 137 is disposed between the initial insulating layer 410 and the first original insulating layer 512, and the first interior adhesion layer 137 does not contact the first exterior wiring layer 516. The second interior adhesion layer 138 is disposed between the initial insulating layer 410 and the second original insulating layer 522, and the second interior adhesion layer 138 does not contact the second exterior wiring layer 526.

Still referring to FIG. 6A, after the pressing step is performed, at least one hole H2 may be formed in the first interior adhesion layer 137, the first original insulating layer 512, and the wiring layer 514 by laser drilling. Similarly, at least one hole H3 may be formed in the second interior adhesion layer 138, the second original insulating layer 522, and the wiring layer 524 by laser drilling.

Referring to FIG. 6A and FIG. 6B, electroplating and/or electroless plating is performed to form at least one via H2′ in the first interior adhesion layer 137, the first original insulating layer 512, and the wiring layer 514 (referring to FIG. 6A). Similarly, electroplating and/or electroless plating is performed to form at least one via H3′ in the second interior adhesion layer 138, the second original insulating layer 522, and the wiring layer 524 (referring to FIG. 6A).

Still referring to FIG. 6B, after the via H2′ and the via H3′ is formed, a photolithography process is performed using a mask (not shown) to form the wiring layer 514 and the wiring layer 524 into the patterned wiring layer 116 and the patterned wiring layer 126, as shown in FIG. 6B.

Referring to FIG. 6B and FIG. 6C, a portion of the interior base board 400, a portion of the first main portion 512a, and a portion of the second main portion 522a are removed to form a through hole TH penetrating along the first direction D1 in the interior base board 400 and expose a portion of the sidewall s3 of the interior base board 400. Specifically, a portion of the initial insulating layer 410 in FIG. 6B is removed to form the interior insulating layer 134 in FIG. 6C.

Still referring to FIG. 6C, after the portion of the first main portion 512a is removed, a portion of a top surface ts1 and the sidewall s4 of the first interior adhesion layer 137 are exposed. After the portion of the second main portion 522a is removed, a portion of a top surface ts2 and the sidewall s5 of the second interior adhesion layer 138 are exposed.

Still referring to FIG. 6C, a portion of the first extended portion 512b is recessed, so that a recess R1 is formed in the first extended portion 512b, in which the recess R1 is disposed relative to the first exterior wiring layer 516. A portion of the second extended portion 522b is recessed, so that a recess R2 is formed in the second extended portion 522b, in which the recess R2 is disposed relative to the second exterior wiring layer 526. In the example of FIG. 6C, a projection of the recess R1 on the interior insulating layer 134 overlaps a projection of the recess R2 on the interior insulating layer 134.

Still referring to FIG. 6C, a first composite material 140a is formed on the top surface ts1 and the sidewall s4 of the first interior adhesion layer 137, and the first composite material 140a is formed on the top surface ts2 and the sidewall s5 of the second interior adhesion layer 138. It could be understood that the first composite material 140a is formed on the above-removing portion of the first main portion 512a and the above-removing portion of the second main portion 522a. Specifically, the first composite material 140a further forms on the sidewall s3 of the removing portion of the interior base board 400 (for example, the interior insulating layer 134).

Referring to FIG. 6C and FIG. 6D, the first exterior reinforcement layer 112 is formed on the first composite material 140a and in the first original insulating layer 512, and the second exterior reinforcement layer 122 is formed on the first composite material 140a and in the second original insulating layer 522 to close the through hole TH and form the cavity CA in the interior base board 400. The cavity CA exposes a portion of the first exterior reinforcement layer 112 and a portion of the second exterior reinforcement layer 122.

Still referring to FIG. 6D, a second composite material 140b covering the first exterior reinforcement layer 112 and the second exterior reinforcement layer 122 is formed. It could be understood that the composite material layer 140 is composed of the first composite material 140a and the second composite material 140b, in which the materials of the first composite material 140a and the second composite material 140b are the same as the material of the composite material layer 140.

Still referring to FIG. 6D, the first exterior adhesion layer 115 is formed on the first original insulating layer 512, and the second exterior adhesion layer 125 is formed on the second original insulating layer 522. Specifically, the first exterior adhesion layer 115 and the second exterior adhesion layer 125 are respectively formed around the composite material layer 140.

Referring to FIG. 6D and FIG. 6E, the first extended portion 512b and the first exterior wiring layer 516 are bended to cover the first main portion 512a. The second extended portion 522b and the second exterior wiring layer 526 are bended to cover the second main portion 522a. Specifically, the recess R1 (referring to FIG. 6D) of the first extended portion 512b is formed relative to the structure of the first exterior reinforcement layer 112 and the second composite material 140b, and the recess R2 (referring to FIG. 6D) of the second extended portion 522b is formed relative to the structure of the second exterior reinforcement layer 122 and the second composite material 140b.

Referring to FIG. 6E and FIG. 6F, a cutting step is performed to separate the first extended portion 512b and the first main portion 512a and separate the second extended portion 522b and the second main portion 522a. It could be understood that the first main portion 512a, the first extended portion 512b, the first exterior wiring layer 516, the second main portion 522a, the second extended portion 522b, and the second exterior wiring layer 526 in the circuit board 100a of FIG. 6F is equivalent to the first exterior insulating layer 113, the second exterior insulating layer 114, the first exterior wiring layer 117, the third exterior insulating layer 123, the fourth exterior insulating layer 124, and the second exterior wiring layer 127 in the circuit board 100 of FIG. 1. The wiring layer 460 and the wiring layer 470 in the circuit board 100a of FIG. 6F is equivalent to the wiring layer 135 and the wiring layer 136 in the circuit board 100 of FIG. 1.

The manufacturing methods of the circuit board 200 in FIG. 2 and the circuit board 300 in FIG. 3 are similar to the manufacturing method of the circuit board 100a in FIG. 6A to FIG. 6F described above, and they would not repeat herein.

The circuit boards of the present disclosure can be widely used in consumer electronic products (for examples, portable devices such as smart phones or tablet computers), automotive fields (for examples, signal transmission between in-vehicle sensors and control units), medical fields (for examples, wearable health monitoring devices or implantable medical devices), aerospace field (for examples, featherweight and highly reliable communication systems), Internet of Things (IoT) (for examples, construction of miniaturized sensor networks in smart homes, smart cities, etc.), but is not limited thereto.

In summary, the circuit board provided by the present disclosure has the first exterior reinforcement layer, the second exterior reinforcement layer, and the composite material layer embedded in the circuit board, so that electronic components can be additionally disposed at relative positions on both sides of the outside of the circuit board, thereby increasing the degree of freedom of the circuit design, the space utilization rate, and the functional integration capability.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board, comprising:
a first exterior structure comprising a first exterior reinforcement layer disposed in the first exterior structure;
a second exterior structure comprising a second exterior reinforcement layer disposed in the second exterior structure;
an interior structure disposed between the first exterior structure and the second exterior structure, wherein the first exterior structure, the interior structure, and the second exterior structure are stacked in sequence along a first direction, wherein the interior structure has a cavity extending along the first direction, the cavity is formed through the interior structure, the first exterior reinforcement layer is located on a top of the cavity, the cavity exposes a portion of the first exterior reinforcement layer, the second exterior reinforcement layer is located on a bottom of the cavity, and the cavity exposes a portion of the second exterior reinforcement layer; and
a composite material layer surrounding the cavity, the first exterior structure, and the second exterior structure.

2. The circuit board of claim 1, wherein the interior structure further comprises:
an interior insulating layer, wherein the composite material layer is further disposed on a sidewall of the interior insulating layer;
a first interior adhesion layer disposed between the interior insulating layer and the first exterior structure, wherein the composite material layer is further disposed on a sidewall of the first interior adhesion layer; and
a second interior adhesion layer disposed between the interior insulating layer and the second exterior structure, wherein the composite material layer is further disposed on a sidewall of the second interior adhesion layer.

3. The circuit board of claim 2, wherein the first exterior structure further comprises:
a first exterior insulating layer disposed on the first interior adhesion layer;
a second exterior insulating layer disposed on the first exterior insulating layer and the cavity, wherein a portion of the first exterior insulating layer protrudes from a sidewall of the second exterior insulating layer in a second direction, and the second direction is perpendicular to the first direction; and
a first exterior adhesion layer disposed between the first exterior insulating layer and the second exterior insulating layer, wherein the first exterior reinforcement layer is disposed between the second exterior insulating layer and the cavity, and the composite material layer surrounds the first exterior reinforcement layer and contacts the first exterior insulating layer, the first exterior adhesion layer, and the second exterior insulating layer.

4. The circuit board of claim 3, wherein the second exterior structure further comprises:
a third exterior insulating layer disposed on the second interior adhesion layer;
a fourth exterior insulating layer disposed on the third exterior insulating layer and the cavity, wherein a portion of the third exterior insulating layer protrudes from a sidewall of the fourth exterior insulating layer in the second direction; and
a second exterior adhesion layer disposed between the third exterior insulating layer and the fourth exterior insulating layer, wherein the second exterior reinforcement layer is disposed between the fourth exterior insulating layer and the cavity, and the composite material layer surrounds the second exterior reinforcement layer and contacts the third exterior insulating layer, the second exterior adhesion layer, and the fourth exterior insulating layer.

5. The circuit board of claim 4, wherein a width of the second exterior reinforcement layer is greater than a width of the cavity, and a width of the fourth exterior insulating layer is greater than a width of the second exterior reinforcement layer.

6. The circuit board of claim 3, wherein a width of the first exterior reinforcement layer is greater than a width of the cavity, and a width of the second exterior insulating layer is greater than a width of the first exterior reinforcement layer.

7. The circuit board of claim 1, wherein the composite material layer exposes a portion of a surface of the first exterior reinforcement layer facing the cavity, and the composite material layer exposes a portion of a surface of the second exterior reinforcement layer facing the cavity

8. The circuit board of claim 1, wherein the composite material layer is composed of a plurality of columnar materials, the plurality of columnar materials is arranged as a single-layer closed structure, each of the plurality of columnar materials extends a third direction perpendicular to the first direction, and each of the plurality of columnar materials comprises a plurality of ceramic particles, a fiber reinforcement material, and a graphene material.

9. The circuit board of claim 1, wherein materials of the first exterior reinforcement layer and the second exterior reinforcement layer comprise a fiber glass and a thermoset resin.

10. A manufacturing method of a circuit board, comprising:
providing a first original exterior structure, an interior base board, and a second original exterior structure stacked in sequence along a first direction;
wherein the first original exterior structure comprises a first original insulating layer and a first exterior wiring layer facing the interior base board, wherein the first original insulating layer comprises a first main portion and a first extended portion connecting to the first main portion, and the first exterior wiring layer is disposed on the first extended portion;
wherein the second original exterior structure comprises a second original insulating layer and a second exterior wiring layer facing the interior base board, wherein the second original insulating layer comprises a second main portion and a second extended portion connecting to the second main portion, and the second exterior wiring layer is disposed on the second extended portion;
removing a portion of the interior base board, a portion of the first main portion, and a portion of the second main portion to form a through hole penetrating along the first direction in the interior base board and expose a portion of a sidewall of the interior base board;
forming a first composite material on the portion of the sidewall of the interior base board, the portion of the first main portion, and the portion of the second main portion;
forming a first exterior reinforcement layer on the first composite material and in the first original insulating layer, and forming a second exterior reinforcement layer on the first composite material and in the second original insulating layer to close the through hole and form a cavity in the interior base board, wherein the cavity exposes a portion of the first exterior reinforcement layer and a portion of the second exterior reinforcement layer;
forming a second composite material covering the first exterior reinforcement layer and the second exterior reinforcement layer;
bending the first extended portion and the first exterior wiring layer to cover the first main portion;
bending the second extended portion and the second exterior wiring layer to cover the second main portion; and
performing a cutting step to separate the first extended portion and the first main portion and separate the second extended portion and the second main portion.

11. The manufacturing method of the circuit board of claim 10, further comprising:
forming a first interior adhesion layer between the first original exterior structure and the interior base board;
forming a second interior adhesion layer between the second original exterior structure and the interior base board;
after removing the portion of the first main portion, exposing a portion of a top surface of the first interior adhesion layer;
after removing the portion of the second main portion, exposing a portion of a top surface of the second interior adhesion layer;
forming the first composite material on the top surface and a sidewall of the first interior adhesion layer; and
forming the first composite material on the top surface and a sidewall of the second interior adhesion layer.

12. The manufacturing method of the circuit board of claim 11, wherein the first interior adhesion layer does not contact the first exterior wiring layer, and the second interior adhesion layer does not contact the second exterior wiring layer.

13. The manufacturing method of the circuit board of claim 10, further comprising:
before bending the first extended portion and the first exterior wiring layer, forming a first exterior adhesion layer on the first original insulating layer; and
before bending the second extended portion and the second exterior wiring layer, forming a second exterior adhesion layer on the second original insulating layer.

14. The manufacturing method of the circuit board of claim 10, further comprising:
before bending the first extended portion and the first exterior wiring layer and bending the second extended portion and the second exterior wiring layer, recessing a portion of the first extended portion and a portion of the second extended portion.

15. The manufacturing method of the circuit board of claim 10, wherein the interior base board further comprises an interior insulating layer, a projection of the first exterior wiring layer on the interior insulating layer overlaps a projection of the second exterior wiring layer on the interior insulating layer.
